(19) United States
(12) Patent Application Publication
(10) Pub. No.: US 2020/0133669 A1
(43) Pub. Date: Apr. 30, 2020

(54) TECHNIQUES FOR DYNAMIC PROXIMITY BASED ON-DIE TERMINATION

(71) Applicant: Intel Corporation, Santa Clara, CA (US)

(72) Inventors: Shekoufeh QAWAMI, El Dorado Hills, CA (US); Rajesh SUNDARAM, Folsom, CA (US); Sheldon G. HIEMSTRA, Vancouver (CA); Setul M. SHAH, Folsom, CA (US); Andrew MORNING-SMITH, Vancouver (CA); Sowmiya JAYACHANDRAN, Portland, OR (US)

(21) Appl. No.: 16/725,521

(22) Filed: Dec. 23, 2019

(51) Int. Cl. G06F 9/30; G11C 7/10; G11C 11/4093; H03K 19/00; G11C 5/04

(52) U.S. Cl. CPC G06F 9/3004; G11C 7/1084; G11C 11/4093; G11C 7/1057; G11C 5/04; G06F 9/30101; G06F 9/3012; H03K 19/0005

(57) ABSTRACT

Techniques for proximity based on-die termination (ODT) include a memory device determining what ODT setting to apply during execution of a command by another memory device that is coupled to a same data channel as the memory device based on the memory device's proximity to the other memory device and whether the command is a read command or a write command.

### TECHNICAL FIELD

Examples described herein are generally related to techniques for on die termination at a memory device.

### BACKGROUND

In some memory systems having memory devices or dies coupled with an application specific integrated circuit (ASIC) serving as a controller, multiple on die termination (ODT) pins are provided both on the ASIC and memory devices to control values for internal resistance termination (RTT) and on and off timing for ODT at the memory devices or dies. These ODT pins typically require cooperation between the ASIC and a given memory device or die to account for an appropriate amount of time for RTT during a read or write operation to the memory device or die.

### BRIEF DESCRIPTION OF THE DRAWINGS

FIG. 1 illustrates an example first system.

FIG. 2 illustrates an example first register table.

FIG. 3 illustrates an example second register table.

FIG. 4 illustrates an example third register table.

FIG. 5 illustrates an example second system.

FIG. 6 illustrates an example first logic flow.

FIG. 7 illustrates an example apparatus.

FIG. 8 illustrates an example second logic flow.

FIG. 9 illustrates an example storage medium.

FIG. 10 illustrates an example third system.

### DETAILED DESCRIPTION

Memory devices coupled with an ASIC serving as a controller to control access to the memory devices may be deployed in a storage device such as, but not limited to, a solid state drive (SSD) or a dual in-line memory module (DIMM). In some examples, multiple memory devices or dies may be included in groups of dies that may be referred to as a “package”. For these examples, multiple packages may be coupled with the ASIC via a single data or DQ channel. Also, multiple DQ channels (e.g., 4 to 10 or more) may be included in some SSD solutions or implementations. Typically, internal resistance termination (RTT) may be used at each memory device or die included in a package to reduce noise due to reflection and to improve signal integrity to packages coupled with the ASIC via DQ channels. Current RTT requirements are typically met by using multiple ODT pins per DQ channel to activate RTT at each memory device. This adds up to a need for 10's of ODT pins on an ASIC serving as a controller for these SSD solutions. The need for 10's of pins may negatively impact costs for these types of SSD solutions and may also negatively limit a form factor for the ASIC.

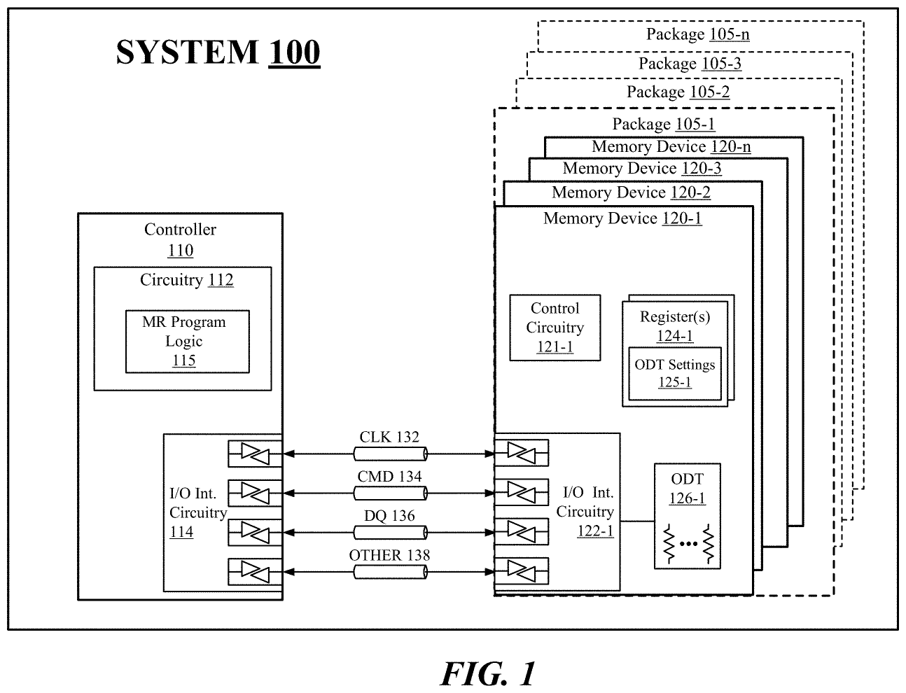

FIG. 1 illustrates an example system 100. In some examples, as shown in FIG. 1, system 100 includes a controller 110 coupled with a plurality of memory devices 120 included in a plurality of packages 105. In some examples, system 100 may be a storage device such as, but not limited to, an SSD. As disclosed herein, reference to a memory device or memory devices such as memory devices 120 may include one or more different memory types. Memory devices, as described herein, may refer to non-volatile or volatile memory types. Some non-volatile memory types may be block addressable such as NAND or NOR technologies. Other non-volatile memory types may be byte or block addressable types of non-volatile memory having a 3-dimensional (3-D) cross-point memory structure that includes, but is not limited to, chalcogenide phase change material (e.g., chalcogenide glass) hereinafter referred to as “3-D cross-point memory”. Non-volatile types of memory may also include other types of byte or block addressable non-volatile memory such as, but not limited to, multi-threshold level NAND flash memory, NOR flash memory, single or multi-level phase change memory (PCM), resistive memory, nanowire memory, ferroelectric transistor random access memory (FeTRAM), anti-ferroelectric memory, resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory, a magnetoresistive random access memory (MRAM) that incorporates memristor technology, spin transfer torque MRAM (STT-MRAM), or a combination of any of the above.

Descriptions herein referring to a “RAM” or “RAM device” can apply to any memory device that allows random access, whether volatile or non-volatile. Descriptions referring to a dynamic random access memory (DRAM), or synchronous DRAM (SDRAM), DRAM device or SDRAM device may refer to a volatile random access memory device. The memory device, SDRAM or DRAM may refer to the die itself, to a packaged memory product that includes one or more dies, or both. In some examples, a system with volatile memory that needs to be refreshed may also include at least some non-volatile memory to support at least a minimal level of memory persistence.

Controller 110, as shown in FIG. 1, may represent a controller to access memory devices 120 located on packages 105. In some examples, system 100 may be a storage device and controller 110 may be an ASIC designed for a specific solution to access memory devices 120. For examples, a storage enterprise solution for an SSD deployed in data center environment. Also, circuitry 112 of controller 110 may support logic and/or features to generate memory access commands in response to access requests to memory devices 120 (e.g., from a processor of a host computing platform that may host system 100). In some examples, controller 110 may access one or more memory device 120. Groups of memory devices 120 located on separate packages 105 may be organized and managed through different channels, where these channels may couple in parallel to controller 110 via buses and signal lines. Each channel may be independently operable. Thus, separate channels may be independently accessed and controlled, and the timing, data transfer, command and address exchanges, and other operations may be separate for each channel. Coupling may refer to an electrical coupling, communicative coupling, physical coupling, or a combination of these. Physical coupling may include direct contact. Electrical coupling, for example, includes an interface or interconnection that allows electrical flow between components, or allows signaling between components, or both. Communicative coupling, for example, includes connections, including wired or wireless, that enable components to exchange data.

According to some examples, controller 110 includes I/O interface circuitry 114 to couple to a memory bus, such as a memory channel as referred to above. I/O interface circuitry 114 (as well as I/O interface circuitry 122 of memory devices 1120 may include pins, pads, connectors, signal lines, traces, or wires, or other hardware to connect the devices, or a combination of these. I/O interface circuitry 114 may include a hardware interface. As shown in FIG. 1, I/O interface circuitry 114 includes at least drivers/transceivers for signal lines. Commonly, wires within an integrated circuit interface couple with a pad, pin, or connector to interface signal lines or traces or other wires between devices. I/O interface circuitry 114 can include drivers, receivers, transceivers, or termination, or other circuitry or combinations of circuitry to exchange signals on the signal lines between controller 110 and groups of memory devices 120 located on separate packages 105. The exchange of signals includes at least one of transmit or receive. While shown as coupling I/O interface circuitry 114 from controller 110 to I/O interface circuitry 122 of memory devices 120, it will be understood that in an implementation of system 100 where groups of memory devices 120 are accessed in parallel, multiple memory devices 120 at multiple packages 105 include I/O interface circuitry to the same interface of controller 110.

In some examples, controller 110 may be coupled with memory devices 120 via multiple signal lines. The multiple signal lines may include at least a clock (CLK) 132, a command/address (CMD) 134, and write data (DQ) and read data (DQ) 136, and zero or more other signal lines 138. According to some examples, a composition of signal lines coupling memory controller 110 to memory device(s) 120 may be referred to collectively as a memory bus. The signal lines for CMD 134 may be referred to as a “command bus”, a “C/A bus” or an ADD/CMD bus, or some other designation indicating the transfer of commands. The signal lines for DQ 136 may be referred to as a “data bus”.

According to some examples, independent channels may have different clock signals, command buses, data buses, and other signal lines. For these examples, system 100 may be considered to have multiple “buses,” in the sense that an independent interface path may be considered a separate bus. It will be understood that in addition to the signal lines shown in FIG. 1, a bus may also include at least one of strobe signaling lines, alert lines, auxiliary lines, or other signal lines, or a combination of these additional signal lines. It will also be understood that serial bus technologies can be used for transmitting signals between controller 110 and memory devices 120. An example of a serial bus technology is 8B10B encoding and transmission of high-speed data with embedded clock over a single differential pair of signals in each direction. In some examples, CMD 134 represents signal lines shared in parallel with multiple memory devices 120 located on a given package 105. For example, signal lines shared in parallel with memory devices 120-1 to 120-n of package 105-1, where “n” is any whole positive integer >3. In other examples, memory devices 120 of a given package 105 share encoding command signal lines of CMD 134, and each memory device may have a separate chip select (CS #) signal line to select individual memory devices 120 for the given package 105.

In some examples, the bus between controller 110 and memory devices 120 includes a subsidiary command bus routed via signal lines included in CMD 134 and a subsidiary data bus to carry the write and read data routed via signal lines included in DQ 136. In some examples, CMD 134 and DQ 136 may separately include bidirectional lines. In other examples, DQ 136 may include unidirectional write signal lines to write data to memory devices 120 and unidirectional lines to read data from memory devices 120.

According to some examples, in accordance with a chosen memory technology and system design, signals lines included in other 138 may augment a memory bus or subsidiary bus. For example, strobe line signal lines for a DQS. Based on a design of system 100, or memory technology implementation, a memory bus may have more or less bandwidth per memory device included in memory devices 120. The memory bus may support memory devices included in memory devices 120 that have either a x32 interface, a x16 interface, a x8 interface, or other interface. The convention “xW,” where W is an integer that refers to an interface size or width of the interface of memory devices 120, which represents a number of signal lines to exchange data with controller 110. The interface size of these memory devices may be a controlling factor on how many memory devices may be used concurrently per channel in system 100 or coupled in parallel to the same signal lines. In some examples, high bandwidth memory devices, wide interface memory devices, or stacked memory devices, or combinations, may enable wider interfaces, such as a x128 interface, a x256 interface, a x512 interface, a x1024 interface, or other data bus interface widths.

In some examples, memory devices 120 and controller 110 exchange data over a data bus via signal lines included in DQ 136 in a burst, or a sequence of consecutive data transfers. The burst corresponds to a number of transfer cycles, which is related to a bus frequency. A given transfer cycle may be a whole clock cycle for transfers occurring on a same clock or strobe signal edge (e.g., on the rising edge). In some examples, every clock cycle, referring to a cycle of the system clock, may be separated into multiple unit intervals (UIs), where each UI is a transfer cycle. For example, double data rate transfers trigger on both edges of the clock signal (e.g., rising and falling). A burst can last for a configured number of Uls, which can be a configuration stored in a register, or triggered on the fly. For example, a sequence of eight consecutive transfer periods can be considered a burst length 8 (BL8), and each memory device 120 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

According to some examples, memory devices 120 represent memory resources for system 100. For these examples, each memory device of memory devices 120 may represent a separate memory die. Groups of memory die may be included on separate packages 105. A given memory device of memory devices 120 may include I/O interface circuitry 122 and may have a bandwidth determined by an interface width associated with an implementation or configuration of the given memory device (e.g., x16 or x8 or some other interface bandwidth). I/O interface circuitry 122 may enable the memory device to interface with controller 110. I/O interface circuitry 122 may include a hardware interface and operate in coordination with I/O interface circuitry 114 of controller 110.

In some examples, memory devices 120 and packages 105 may be incorporated into a same, larger package as controller 110. For example, incorporated in a multi-chip-module (MCM), a package-on-package with through-silicon via (TSV), or other techniques or combinations. It will be appreciated that for these and other examples, controller 110 may also be part of or integrated with a processor.

According to some examples, as shown in FIG. 1, memory device 120 include one or more register(s) 124. Registers 124 may represent one or more storage devices or storage locations that provide configuration or settings for configuration and/or operation of memory device 120. In one example, register(s) 124 may provide a storage location for memory devices 120 to store data for access by controller 110 as part of a control or management operation. For example, register(s) 124 may include one or more mode registers (MRs) and/or may include one or more multipurpose registers.

In some examples, writing to or programming one or more registers of register(s) 124 may configure memory devices 120 to operate in different “modes”. For these examples, command information written to or programmed to the one or more registers may trigger different modes within memory devices 120. Additionally, or in the alternative, different modes can also trigger different operations from address information or other signal lines depending on the triggered mode. Programmed settings of register(s) 124 may indicate or trigger configuration of I/O settings. For example, configuration of timing, termination, on-die termination (ODT), driver configuration, or other I/O settings. As described in more detail below, circuitry 112 of controller 110 may execute mode register (MR) program logic 115 to program one or more register(s) 124 to set or program ODT settings 125. Control circuitry 121 of memory devices 120 may be capable of accessing ODT settings 125 to implement a command based dynamic ODT scheme. Use of the command based dynamic ODT scheme may enable MR program logic 115 to program the one or more register(s) 124 to establish ODT settings 125 and remove the need for ODT pins in I/O interface circuitry 114 to activate ODT settings at memory devices 120. In some examples, 10's of ODT pins may be removed from I/O interface circuitry 114 of controller 110 when a command based dynamic ODT scheme is implemented. ODT pins may also be removed from I/O interface circuitry 122 of memory devices 120, but in some examples ODT pins may remain in order for memory devices 120 to still be capable of operating with legacy controllers that still utilize ODT pins to activate ODT settings.

According to some examples, memory devices 120 include ODT 126 as part of the interface hardware associated with I/O interface circuitry 122. ODT 126 may provide settings for impedance to be applied to the interface to specified signal lines. For example, ODT 126 may be configured to apply impedance to signal lines include in DQ 136 or CMD 134. The ODT settings for ODT 126 may be changed based on the command based dynamic ODT scheme mentioned above. As described more below, the command based dynamic ODT scheme may be based on the type of memory access (e.g., read or write) and proximity of a terminating memory device located on a given package to the accessed memory device that may be on a same or different package. ODT settings indicated in ODT settings 125 for ODT 126 may affect timing and reflections of signaling on terminated signal lines included in, for example, CMD 134 or DQ 136. Determining what ODT settings 125 to use to set ODT 126 can enable higher-speed operation with improved matching of applied impedance and loading. Impedance and loading may be applied to specific signal lines of I/O interface circuitry 122, (e.g., CMD 134 and DQ 136) and is not necessarily applied to all signal lines.

In some examples, as shown in FIG. 1, memory devices 120 include control circuitry 121. Control circuitry 121 may execute logic within memory devices 120 to control internal operations within memory devices 120. For example, control circuitry 121 decodes commands sent by controller 110 and generates internal operations to execute or satisfy the commands. Control circuitry 121 may be referred to as an internal controller and is separate from controller 1110. Control circuitry 121 may include logic and/or features to determine what mode is selected based on programmed or default settings indicated in register(s) 124 and configure the internal execution of operations for access to a given memory device 120 or other operations based on the selected mode. Control circuitry 121 generates control signals to control the routing of bits within memory devices 120 to provide a proper interface for the selected mode and direct a command to the proper memory locations or addresses of physical memory resources included in the given memory device 120.

Referring again to controller 110, controller 110 includes circuitry 112, which may execute logic and/or features to generate commands to send to memory devices 120. The generation of the commands can refer to the command prior to scheduling, or the preparation of queued commands ready to be sent. Generally, the signaling in memory subsystems includes address information within or accompanying the command to indicate or select one or more memory locations where memory devices 120 should execute the command. In response to scheduling of transactions for memory devices 120, controller 110 can issue commands via I/O interface circuitry 114 to cause memory devices 120 to execute the commands. In some examples, control circuitry 121 of memory devices 120 receives and decodes command and address information received via I/O interface circuitry 122 from controller 110. Based on the received command and address information, circuitry 112 may control the timing of operations of the logic, features and/or circuitry within memory devices 120 to execute the commands.

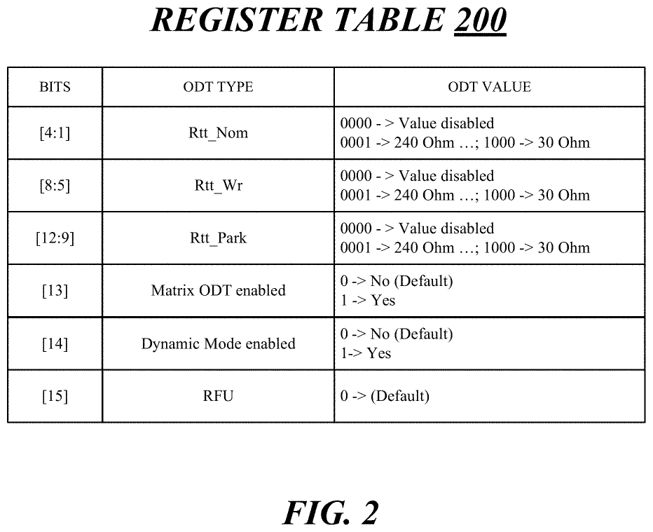

FIG. 2 illustrates an example register table 200. In some examples, as shown in FIG. 2, register table 200 indicates ODT types and settings for a 16 bit register. The 16 bit register, for example, may be included in register(s) 124 of memory devices 120. MR program logic 115 may be capable of setting or programming bits [4:1] to set Rtt_nom, bits [8:5] to set Rtt_Wr, bits [12:9] to set Rtt_park, bit [13] to indicate whether matrix ODT is enabled (e.g., to enable dynamic ODT selection based on proximity), and bit [14] to indicate whether dynamic mode is enabled.

In some examples, matrix ODT may be enabled based on establishment of how a terminating memory device or die is to set its respective ODT setting during access (e.g. during a write operation) to another memory device. For these examples, the terminating memory device's proximity to the accessed memory device may cause the terminating memory device to select from one of at least two separate matrix ODT settings. According to some examples, as described more below, the at least two separate matrix ODT settings may also be set or programmed by MR program logic 115 via a register included in register(s) 124. Examples are not limited to the ODT setting values indicated in register table 200 that range from 240 ohm to 30 ohm and include an ODT disabled option. These ODT settings are provided as examples of a possible range of ODT settings and a disable option.

According to some examples, dynamic mode may be enabled based on establishment of how a non-terminating memory device or die is to set its respective ODT setting during a write access to another memory device. If dynamic mode is enabled, the non-terminating memory device uses the Rtt_park ODT setting indicated in bits [12:9]. If dynamic mode is not enabled, the non-terminating memory device uses a Hi_z (maximum impedance) ODT setting.

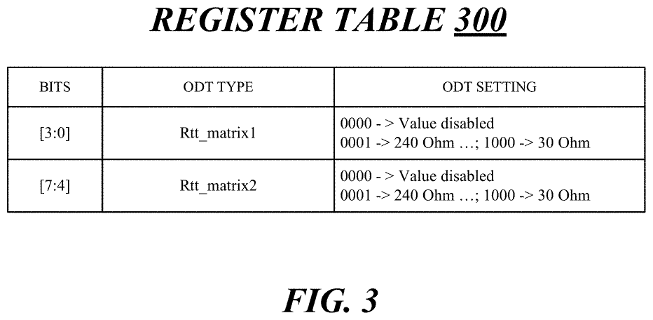

FIG. 3 illustrates an example register table 300. In some examples, as shown in FIG. 3, register table 300 indicates ODT types and settings for an 8 bit register. The 8 bit register, for example, may be included in register(s) 124 of memory devices 20. MR program logic 115 may be capable of setting or programming bits [3:0] to set Rtt_matrix1 and bits [7:4] to set Rtt_matrix2. As described more below, Rtt_matrix 1 may be used if a terminating memory device is located in a same group that includes an accessed memory device being accessed during a write operation and Rtt_matrix 2 may be used if the terminating memory device is located in a different group than the accessed memory device. Examples are not limited to the ODT setting values indicated in register table 200 that range from 240 ohm to 30 ohm and include an ODT disabled option. These ODT settings are provided as examples of a possible range of ODT settings and a disable option. Also, examples, are not limited to just two matrix ODT settings. In some examples, one or more registers may be set to indicate more than two matrix ODT settings.

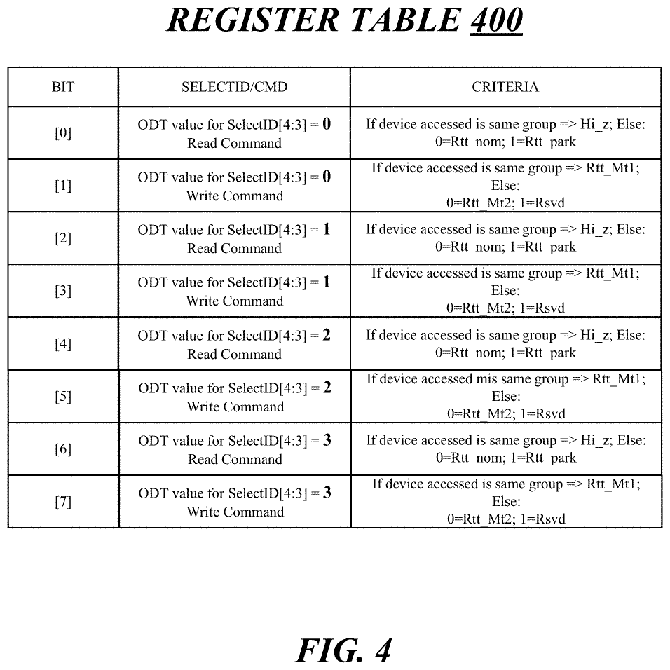

FIG. 4 illustrates an example register table 400. In some examples, as shown in FIG. 4, register table 400, an 8 bit register may indicate a grouping of memory devices into 4 groups having SelectIDs of 0, 1, 2 and 3. For these examples, SelectID for a given group may be indicated in bits [4:3] of a command addressed to access a memory device responsive to either a read or a write command. According to some examples, the 4 groups indicated in register table 300 may be coupled to a same DQ channel with a controller. For example, packages 105-1, 105-2, 105-3 and 105-n may be coupled with controller 110 via a DQ channel routed via DQ 136. For this example, each package may have a terminating memory device or die that will provide termination for its respective package during an access to a memory device 120. For example, memory device 120-n for each package 105 may serve as the terminating memory device for its respective package. Examples are not limited to 4 groups. More or less groups are contemplated by this disclosure.

According to some examples, MR program logic 115 of controller 110 may set or program bits 0-7 of a terminating memory device based on relative physical locations of the terminating memory device in relation to a given group that is being accessed and based on a type of access. For example, memory device 120-n may be the terminating memory device for package 105-1 that has a SelectID=0. MR program logic 115 does not have to program bits [1:0] because those bits represent access to the same group as memory device 120-n and memory device 120-n may be trained to use an ODT setting of Hi_z (maximum impedance) for a read command or to use a matrix ODT setting of Rtt_Mt1 for a write command to group 0. Use of Rtt_Mt1 would prompt memory device 120-n to refer to the ODT setting maintained in register(s) 124-1 for Rtt_Mt1 (e.g., bits [3:0] as shown in register table 300).

In some examples, for a read command, bits [2], [4] and [6] may be separately set or programmed by MR program logic 115 to indicate whether to use Rtt_nom or Rtt_park based on group 0's relative position as being adjacent or near (use Rtt_nom) or not adjacent or far (use Rtt_park) from the group being accessed. For example, if group 0 was located near to group 1, then bit [2] for memory device 120-n would be set to Rtt_nom and memory device 120-n would then refer to the ODT setting maintained in register(s) 124-1 for Rtt_nom (e.g., bits [4:1] as shown in register table 200). Also, if group 0 was located far to groups 2 and 3, then bits [4] and [6] for memory device 120-n would be set to Rtt_park and memory device 120-n would then refer to the ODT setting maintained in register(s) 124-1 for Rtt_park (e.g., bits [12:9] as shown in register table 200).

According to some examples, for a write command, bits [3], [5] and [7] may be separately set or programmed by MR program logic 115 to indicate use of a matrix ODT setting of Rtt_Mt2. For these examples, Rtt_Mt2 is set for these bits because access to any group other than group 0 would prompt memory device 120-n to refer to the ODT setting maintained in register(s) 124-1 for Rtt_Mt2 (e.g., bits [7:4] as shown in register table 300).

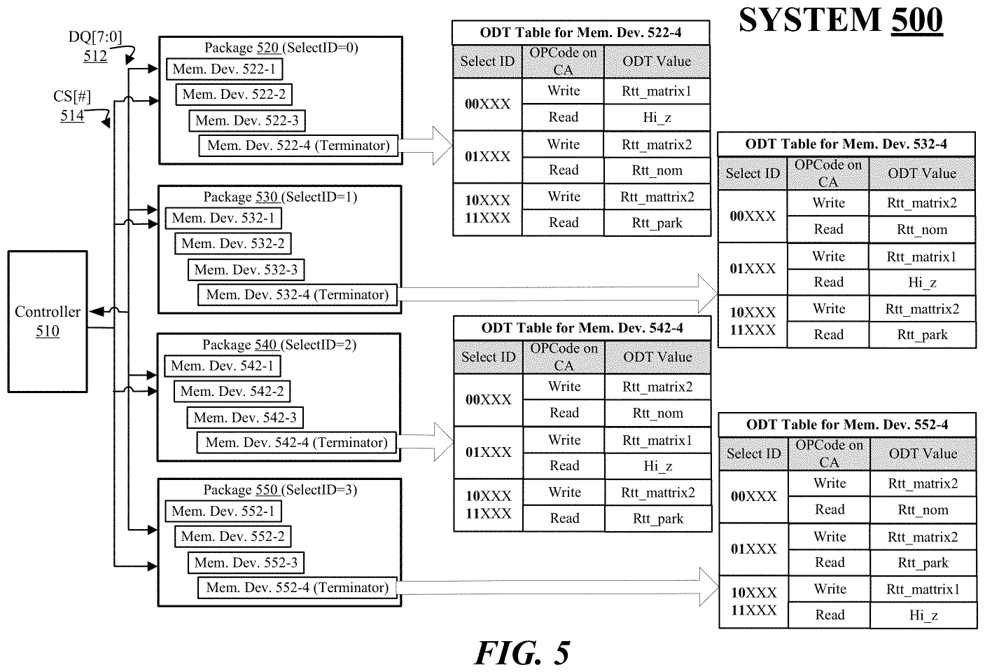

FIG. 5 illustrates an example system 500. In some examples, as shown in FIG. 5, system 500 includes packages 520, 530, 540 and 550 coupled to a controller 510 via a same channel DQ[7:0] 512 that utilizes a chip select (CS) signal via CS[#] 514 to indicate which memory device is to be accessed. For these examples, controller 510 may be similar to controller 110 shown in FIG. 1 and described above. Also, packages 520, 530, 540 and 550 including respective memory devices 522, 532, 542 and 552 may be similar to packages 105 including memory devices 120 shown in FIG. 1 and described above.

According to some examples, a terminator or terminating memory device for each package may be memory device 522-4 for package 520, 532-4 for package 530, memory device 542-4 for package 540 and memory device 552-4 for package 550. Also, package 520 has a SelectID=0, package 530 has a SelectID=1, package 540 has a SelectID=2 and package 550 has a SelectID=3. As shown in FIG. 5, in some examples, the separate ODT tables for the four terminator memory devices indicate a decision matrix for these terminator memory devices to individually determine what ODT setting to be used based on the SelectID of the package being accessed and whether the access is responsive to a write or read command. For these examples, each terminator memory device goes through its respective decision matrix to determine what ODT settings to apply based on command type and relative proximity to an accessed package.

In a first example, the ODT table for memory device 522-4 indicates that if the SelectID is 00XXX this indicates that the accessed memory device is located in a same package or group as memory device 522-4 and that if the access is responsive to a write command, memory device 522-4 is to refer to the register bits that include Rtt_matrix1 to determine what ODT setting to apply while serving as the terminator for a write operation. If the access is responsive to a read command, memory device 522-4 may apply a Hi_z ODT setting.

In a second example, if the SelectID is 01XXX this indicates that the accessed memory device is located on a different package (package 530) that is located near or adjacent to package 520 and that if the access is a write, memory device 522-4 is to refer to the register bits that include Rtt_matrix2 to determine what ODT setting to apply. If the access is responsive to a read command, memory device 522-4 may refer to the register bits that include Rtt_nom to determine what ODT setting to apply.

In a third example, if SelectID is either 10XXX or 11XXX this also indicates a different package, but these packages may be characterized as being located not adjacent to or far relative to package 520. According to the ODT table for memory device 522-4, for this third example, if the access is a write, memory device 522-4 is to refer to the register bits that include Rtt_matrix2 to determine what ODT setting to apply. If the access is responsive to a read command, memory device 522-4 may refer to the register bits that include Rtt_park to determine what ODT setting to apply. The use or Rtt_park rather than Rtt_nom, for this third example, is based on packages 540 and 550 being characterized as far packages in relation to their physical locations relative to package 520.

According to some examples, a postamble may be applied by a non-targeted terminating die to increase clock cycles (if needed) that the non-targeted termination die will hold a selected termination value. The postamble may be needed if data is delayed across multiple memory devices, for example, due to mismatch routings.

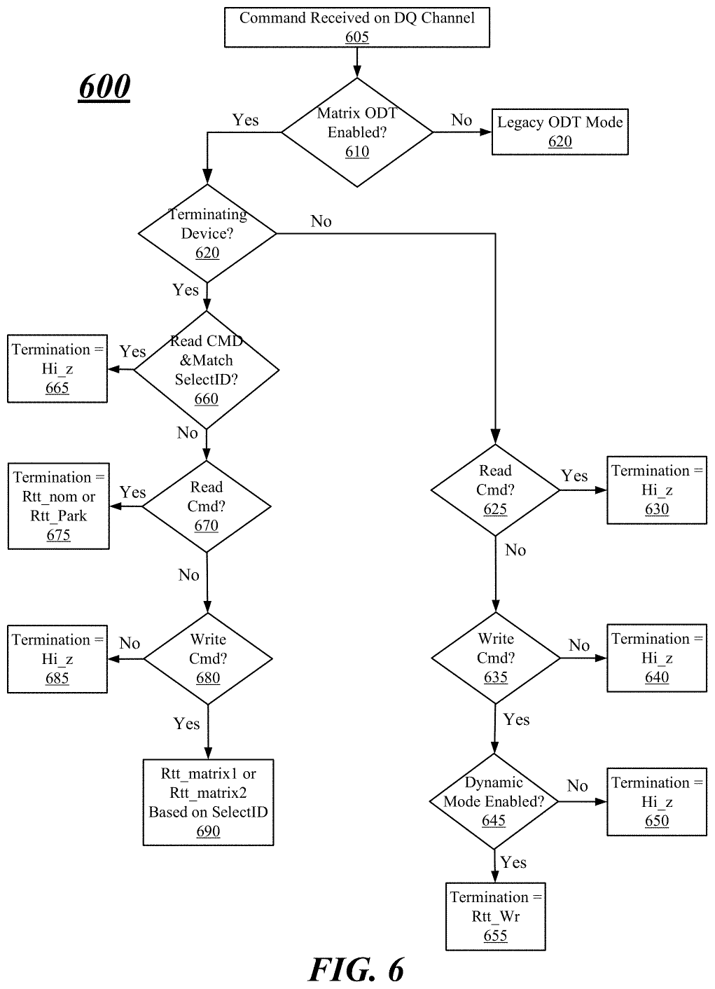

FIG. 6 illustrates an example logic flow 600. In some examples, logic flow 600 may illustrate actions by control circuitry of a memory device to determine ODT settings. For these examples, logic flow 600 may be implemented by control circuitry of such memory devices as memory devices 120 mentioned above for FIGS. 1-4 or such as memory devices 522, 532, 542 or 552 mentioned above for FIG. 5. Also, registers used by these memory devices may be set or programmed as indicated in register tables 200, 300 or 400 as mentioned above for FIGS. 2-4. The registers may be set or programmed by a controller having mode register program logic such as MR program logic 115 of controller 110. Examples are not limited to, to memory devices 120, 522, 532, 542 or 552 included in FIGS. 1 and 5, the ODT settings or ODT types shown in FIGS. 2-4 or to registers programmed or set by MR program logic 115.

Starting at block 605, a command may be received on a DQ channel coupled to multiple packages each having multiple memory devices.

Moving from block 605 to decision block 610, a memory device may determine whether matrix ODT has been enabled. In some examples, the control circuitry of the memory device may read a bit of a register such as bit [13] of the 16 bit register shown in register table 200 to see if matrix ODT has been enable. If bit [13] indicates matrix ODT has not been enabled, logic flow 600 moves to block 615. If bit [13] indicates matrix ODT is enabled, logic flow 600 moves to decision block 620.

Moving from decision block 610 to block 615, the memory device use legacy ODT modes. In some examples, legacy ODT modes may include use of ODT pins on the memory device to receive ODT activation signals to activate ODT settings from a controller coupled with the memory device.

Moving from decision block 610 to decision block 620, the memory device determines whether it is the terminating memory device of a package that includes multiple memory devices or dies. In some examples, the terminating device of each package may be predetermined at the time memory devices were physically placed on a given package. If the memory device is the predetermined termination memory device, logic flow 600 moves to decision block 620. Otherwise, logic flow 600 moves to decision block 625.

Moving from decision block 620 to decision block 625, the memory device determines whether the command is a read command. In some examples, if control circuitry of the memory device determines that the command is not a read command and logic flow 600 moves to decision block 635. Otherwise, logic flow 600 moves to block 630 and the control circuitry causes the memory device to use a Hi_z ODT setting during execution of the command.

Moving from decision block 625 to decision block 635, the memory device determines whether the command is a write command (e.g., an array write, force write or modified write). In some examples, control circuitry of the memory device determines that the command is not a write command and logic flow 600 moves to block 645 and the control circuitry causes the memory device to use a Hi_z ODT setting during execution of the command as indicated by block 630. Otherwise, logic flow 600 moves to decision block 645.

Moving from decision block 635 to decision block 645, the memory device determines whether dynamic mode is enabled. According to some examples, control circuitry of the memory device may read a bit of a register such as bit [14] of the 16 bit register shown in register table 200 to see if dynamic mode has been enabled. If bit [14] indicates dynamic mode has not be enabled, the control circuitry cause the memory device to use a Hi_z ODT setting during a write operation as indicated by block 650. Otherwise, logic flow 600 moves to block 655.

Moving from decision block 645 to block 655, the terminating memory device uses an ODT setting for termination of Rtt_Wr. In some examples, control circuitry of the memory device may read bits of a register such as bits [8:5] of the 16 bit register shown in register table 200 to determine a value to use for Rtt_Wr (e.g., 100 Ohm).

Returning to decision block 620 and moving to decision block 660, the terminating memory device determines whether the command is a read command and whether the SelectID indicated in the read command matches a SelectID for the package that includes the terminating memory device. According to some examples, control circuitry of the terminating memory device determines that the SelectID of the read command matches the SelectID and causes the memory device to use a Hi_z ODT setting during a read operation as shown for block 665. Otherwise, if the command is either not a read command or has a SelectID that doesn't match the SelectID of the terminating memory device's package, logic flow 600 moves to decision block 670.

Moving from decision block 660 to decision block 670, the terminating memory device determines whether the command is read command. According to some examples, control circuitry of the terminating memory device determines that the command is a read command and logic flow 600 moves to decision block 675. Otherwise, logic flow 600 moves to decision block 680.

Moving from decision block 670 to block 675, the terminating memory device selects a type of ODT setting for either Rtt_nom or Rtt_park. In some examples, control circuitry of the terminating memory device may read a bit of a register such as the 8 bit register shown in register table 200 to determine which type of ODT setting to use. For these examples, the control circuitry of the terminating memory device may read a bit of the 8 bit register that corresponds to the SelectID assigned to the package that includes the terminating memory device and to a read command. For example, if the terminating memory device was on a package having a SelectID=0, then the control circuitry may read bit [1] to determine which type of ODT setting to use. Depending on the terminating device's proximity to the memory device being accessed, bit [1] may have been set to a value of “0” (Rtt_nom) if the accessed memory device was on a near package or a value of “1” (Rtt_park) if the accessed memory device was on a far package. Control circuitry of the terminating memory device may read bits of a register such as bits [4:1] or bits [12:9] of the 16 bit register shown in register table 200 to determine a value to respectively use for Rtt_nom or Rtt_park.

Moving from decision block 670 to decision block 680, the terminating memory device determines whether the command is a write command (e.g., an array write, force write or modified write). In some examples, control circuitry of the terminating memory device determines that the command is not a write command and causes the terminating memory device to use a Hi_z ODT setting during execution of the command as indicated by block 685.

Moving from decision block 680 to block 690, the terminating memory device selects a type of ODT setting for either Rtt_matrix1 or Rtt_matrix 2 based on the SelectID indicated in the command. In a first example, if the SelectID matches the SelectID for the package that includes the terminating memory device, then Rtt_matrix1 is selected. For this first example, the control circuitry of the terminating memory device may read bits of a register such as bits [3:0] of the 8 bit register shown in register table 300 to determine a value to use for Rtt_matrix1. In a second example, if the SelectID does not match the SelectID for the package that includes the terminating memory device, then Rtt_matrix2 is selected. For this second example, the control circuitry of the terminating memory device may read bits of a register such as bits [7:4] of the 8 bit register shown in register table 300 to determine a value to use for Rtt_matrix2.

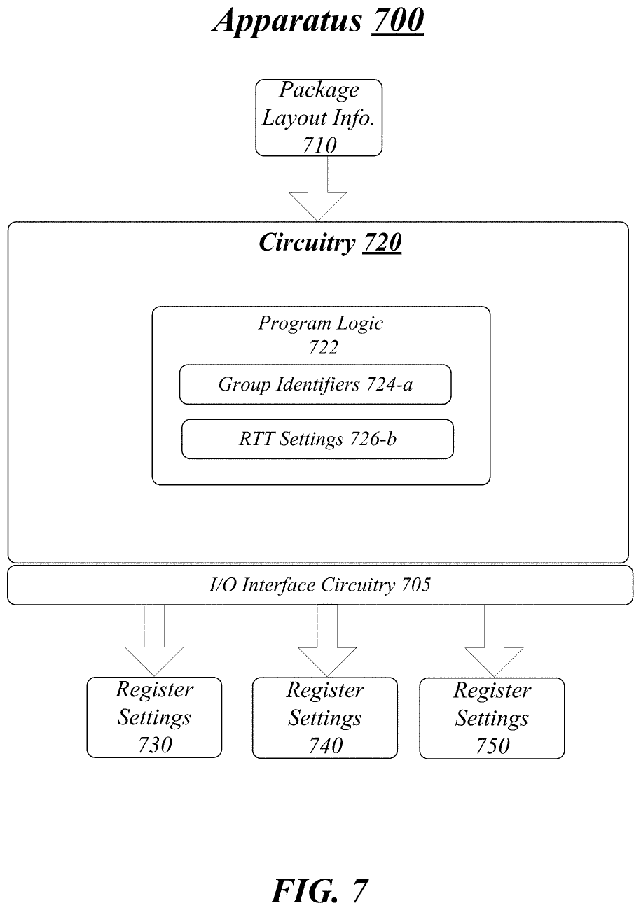

FIG. 7 illustrates an example block diagram for apparatus 700. Although apparatus 700 shown in FIG. 7 has a limited number of elements in a certain topology, it may be appreciated that apparatus 700 may include more or less elements in alternate topologies as desired for a given implementation.

According to some examples, apparatus 700 may be supported by circuitry 720 of a controller such as circuitry 112 of controller 110. Circuitry 720 may be arranged to execute logic or one or more firmware implemented modules, components or features of the logic. It is worthy to note that “a” and “b” and “c” and similar designators as used herein are intended to be variables representing any positive integer. Thus, for example, if an implementation sets a value for a=4, then a complete set of software or firmware for modules, components of logic 722-a may include logic 722-1, 722-2, 722-3 or 722-4. The examples presented are not limited in this context and the different variables used throughout may represent the same or different integer values. Also, “module”, “component” or “feature” may also include firmware stored in computer-readable or machine-readable media, and although types of features are shown in FIG. 7 as discrete boxes, this does not limit these types of features to storage in distinct computer-readable media components (e.g., a separate memory, etc.) or implementation by distinct hardware components (e.g., separate application-specific integrated circuits (ASICs) or field programmable gate arrays (FPGAs)).

According to some examples, circuitry 720 may include one or more ASICs or FPGAs and, in some examples, at least some logic 722-a may be implemented as hardware elements of these ASICs or FPGAs.

According to some examples, as shown in FIG. 7 apparatus 700 may include a I/O interface circuitry 705 to couple with one or more memory devices.

In some examples, apparatus 700 may also include a program logic 722. Program logic 722 may be executed or supported by circuitry 720 to program a first register at a first memory device via I/O interface circuitry 705 to cause the first register to indicate multiple ODT types to select when the first memory device is a terminating memory device for a first group of memory devices. The multiple ODT types may be based on whether a read command or a write command is to be executed by a second memory device included in the first group of memory device or is to be executed by a third memory device included in a second group of memory devices. For these examples, program logic 722 may base the programming of the first register on packet layout information received via packet layout information 710 that indicates the relative positioning of the first memory device compared to the second and third memory devices. For examples, if these memory devices are located on same or different packages than the first memory device. Also, RTT setting 726-b (e.g., maintained in a lookup table) may indicate what ODT types to program to the first register at the first memory device based, at least in part, on the packet layout information. Register settings 730 may indicate how the first register is programmed to indicate the multiple ODT types to select by the first memory device.

According to some examples, Program logic 722 may also be executed or supported by circuitry 720 to program a second register at the first memory device via the I/O interface circuitry to cause the second register to indicate at least two ODT types having separate ODT settings to apply based on whether a write command is to be executed by the second memory device or the third memory device. Program logic 722 may also base the programming of the second register on the packet layout information received via packet layout information 705. Register settings 740 may indicate how the second register is programmed.

In some examples, the first group of memory devices located on a first package assigned a first group identifier, the second group of memory devices may be located on a second package assigned to a second group identifier. A fourth memory device may be included in a third group of memory devices that is located on a third package assigned a third group identifier. The first and the second and the third packages may be coupled to I/O interface circuitry 705 via a same data bus. The second package may be located adjacent or near to the first package. For this examples, the third package is not located adjacent to the first package. Program logic 722 may also be executed or supported by circuitry 720 to program a third register at the first memory device to indicate a first ODT setting and a second ODT setting to selectively apply when the first memory device is the terminating memory device for the first group of memory devices and the command is a read command. The first memory device is to apply the first ODT setting if the read command is to the third memory device or is to apply the second ODT setting if the read command is to the fourth memory device. Program logic 722 may also base the programming of the third register on the packet layout information received via packet layout information 710. Register settings 750 may indicate how the third register is programmed.

In some examples, program logic 722 may also program the first register, the second register or the third register to indicate a postamble time via which the first memory device is to apply a selected ODT setting. The postamble time to indicate one or more additional clock cycles to apply the selected ODT setting.

Various components of apparatus 700 may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Example connections include parallel interfaces, serial interfaces, and bus interfaces.

Included herein is a set of logic flows representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware embodiments, a logic flow may be implemented by computer executable instructions stored on at least one non-transitory computer readable medium or machine readable medium, such as an optical, magnetic or semiconductor storage. The embodiments are not limited in this context.

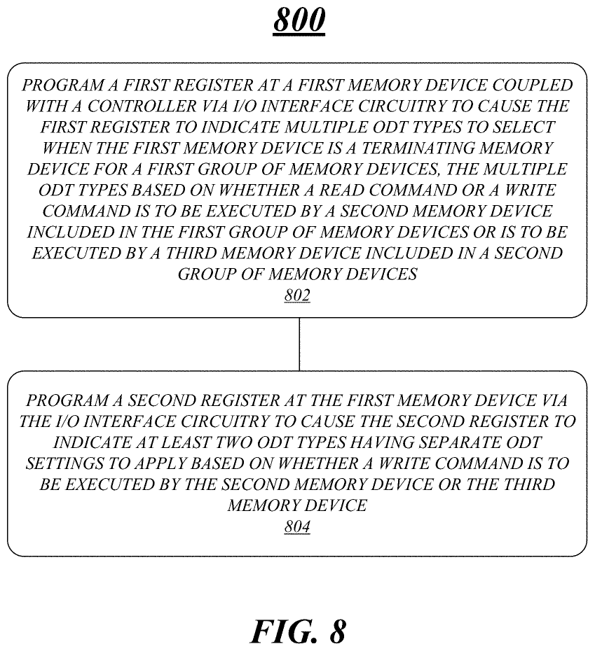

FIG. 8 illustrates an example logic flow 800. Logic flow 800 may be representative of some or all of the operations executed by one or more logic, features, or devices described herein, such as apparatus 700. More particularly, logic flow 800 may be implemented by program logic 722.

According to some examples, logic flow 800 at block 802 may program a first register at a first memory device coupled with a controller via I/O interface circuitry to cause the first register to indicate multiple on-die termination ODT types to select when the first memory device is a terminating memory device for a first group of memory devices, the multiple ODT types based on whether a read command or a write command is to be executed by a second memory device included in the first group of memory devices or is to be executed by a third memory device included in a second group of memory devices. For these examples, program logic 722 may program the first register.

In some examples, logic flow 800 at block 804 may program a second register at the first memory device via the I/O interface circuitry to cause the second register to indicate at least two ODT types having separate ODT settings to apply based on whether a write command is to be executed by the second memory device or the third memory device. For these examples, program logic 722 may program the second register.

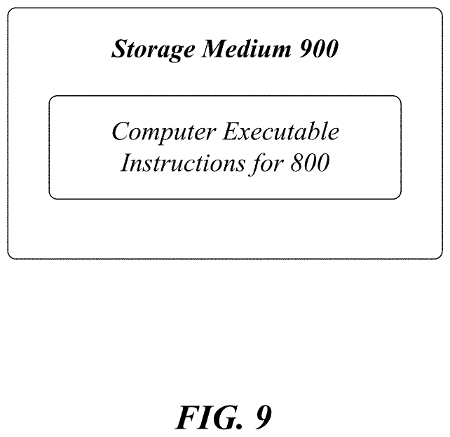

FIG. 9 illustrates an example storage medium 900. In some examples, storage medium 900 may be an article of manufacture. Storage medium 900 may include any non-transitory computer readable medium or machine readable medium, such as an optical, magnetic or semiconductor storage. Storage medium 900 may store various types of computer executable instructions, such as instructions to implement logic flow 800. Examples of a computer readable or machine readable storage medium may include any tangible media capable of storing electronic data, including volatile memory or non-volatile memory, removable or non-removable memory, erasable or non-erasable memory, writeable or re-writeable memory, and so forth. Examples of computer executable instructions may include any suitable type of code, such as source code, compiled code, interpreted code, executable code, static code, dynamic code, object-oriented code, visual code, and the like. The examples are not limited in this context.

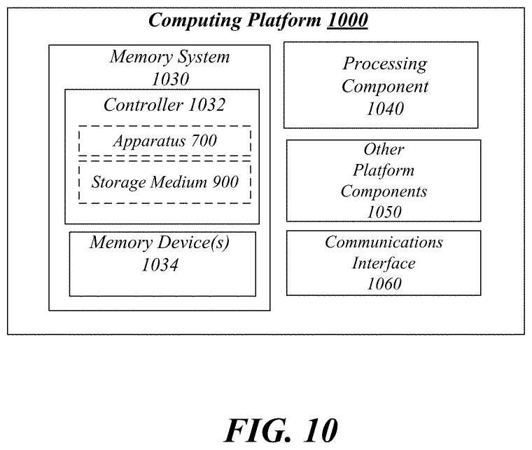

FIG. 10 illustrates an example computing platform 1000. In some examples, as shown in FIG. 10, computing platform 1000 may include a memory system 1030, a processing component 1040, other platform components 1050 or a communications interface 1060. According to some examples, computing platform 1000 may be implemented in a computing device.

According to some examples, memory system 1030 may include a controller 1032 and memory device(s) 1034. For these examples, logic and/or features resident at or located at controller 1032 may execute at least some processing operations or logic for apparatus 700 and may include storage media that includes storage medium 900. Also, memory device(s) 1034 may include similar types of volatile or non-volatile memory (not shown) that are described above for memory devices 120 shown in FIG. 1 or memory devices 522, 532, 542 or 552 shown in FIG. 5. In some examples, controller 1032 may be part of a same die with memory device(s) 1034. In other examples, controller 1032 and memory device(s) 1034 may be located on a same die or integrated circuit with a processor (e.g., included in processing component 1040). In yet other examples, controller 1032 may be in a separate die or integrated circuit coupled with memory device(s) 1034.

According to some examples, Processing components 1040 may include various hardware elements, software elements, or a combination of both. Examples of hardware elements may include devices, logic devices, components, processors, microprocessors, management controllers, companion dice, circuits, processor circuits, circuit elements (e.g., transistors, resistors, capacitors, inductors, and so forth), integrated circuits, ASICs, programmable logic devices (PLDs), digital signal processors (DSPs), FPGAs, memory units, logic gates, registers, semiconductor device, chips, microchips, chip sets, and so forth. Examples of software elements may include software components, programs, applications, computer programs, application programs, device drivers, system programs, software development programs, machine programs, operating system software, middleware, firmware, software modules, routines, subroutines, functions, methods, procedures, software interfaces, application program interfaces (APIs), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given example.

In some examples, other platform components 1050 may include common computing elements, memory units (that include system memory), chipsets, controllers, peripherals, interfaces, oscillators, timing devices, video cards, audio cards, multimedia input/output (I/O) components (e.g., digital displays), power supplies, and so forth. Examples of memory units or memory devices may include without limitation various types of computer readable and machine readable storage media in the form of one or more higher speed memory units, such as read-only memory (ROM), random-access memory (RAM), dynamic RAM (DRAM), Double-Data-Rate DRAM (DDRAM), synchronous DRAM (SDRAM), static RAM (SRAM), programmable ROM (PROM), erasable programmable ROM (EPROM), electrically erasable programmable ROM (EEPROM), flash memory, polymer memory such as ferroelectric polymer memory, ovonic memory, phase change or ferroelectric memory, silicon-oxide-nitride-oxide-silicon (SONOS) memory, magnetic or optical cards, an array of devices such as Redundant Array of Independent Disks (RAID) drives, solid state memory devices (e.g., USB memory), solid state drives (SSD) and any other type of storage media suitable for storing information.

In some examples, communications interface 1060 may include logic and/or features to support a communication interface. For these examples, communications interface 1060 may include one or more communication interfaces that operate according to various communication protocols or standards to communicate over direct or network communication links. Direct communications may occur via use of communication protocols or standards described in one or more industry standards (including progenies and variants) such as those associated with the PCIe specification, the NVMe specification or the I3C specification. Network communications may occur via use of communication protocols or standards such those described in one or more Ethernet standards promulgated by the Institute of Electrical and Electronics Engineers (IEEE). For example, one such Ethernet standard promulgated by IEEE may include, but is not limited to, IEEE 802.3-2018, Carrier sense Multiple access with Collision Detection (CSMA/CD) Access Method and Physical Layer Specifications, Published in August 2018 (hereinafter “IEEE 802.3 specification”). Network communication may also occur according to one or more OpenFlow specifications such as the OpenFlow Hardware Abstraction API Specification. Network communications may also occur according to one or more Infiniband Architecture specifications.

Computing platform 1000 may be part of a computing device that may be, for example, user equipment, a computer, a personal computer (PC), a desktop computer, a laptop computer, a notebook computer, a netbook computer, a tablet, a smart phone, embedded electronics, a gaming console, a server, a server array or server farm, a web server, a network server, an Internet server, a work station, a mini-computer, a main frame computer, a supercomputer, a network appliance, a web appliance, a distributed computing system, multiprocessor systems, processor-based systems, or combination thereof. Accordingly, functions and/or specific configurations of computing platform 1000 described herein, may be included or omitted in various embodiments of computing platform 1000, as suitably desired.

The components and features of computing platform 1000 may be implemented using any combination of discrete circuitry, ASICs, logic gates and/or single chip architectures. Further, the features of computing platform 1000 may be implemented using microcontrollers, programmable logic arrays and/or microprocessors or any combination of the foregoing where suitably appropriate. It is noted that hardware, firmware and/or software elements may be collectively or individually referred to herein as “logic”, “circuit” or “circuitry.”

It should be appreciated that the exemplary computing platform 1000 shown in the block diagram of FIG. 10 may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” and may be similar to IP blocks. IP cores may be stored on a tangible, machine readable medium and supplied to various customers or manufacturing facilities to load into the fabrication machines that actually make the logic or processor.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

Some examples may include an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled” or “coupled with”, however, may also mean that two or more elements are not in direct contact with each other, but yet still co-operate or interact with each other.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

The follow examples pertain to additional examples of technologies disclosed herein.

### Example 1

An example memory device may include one or more registers arranged to maintain ODT settings and control circuitry. The control circuitry may receive an indication that a command is to be executed by a separate memory device coupled with a same data channel. The control circuitry may also read the one or more registers to determine what ODT setting to apply during execution of the command based on a first group identifier that indicates the separate memory device's proximity to the memory device and based on whether the command is a read command or a write command.

### Example 2

The memory device of example 1, the memory device may be located on a first package that includes the separate memory device, the memory device arranged to be a terminating memory device for the first package.

### Example 3

The memory device of example 2, the first group identifier may be assigned to the first package to indicate that the separate memory device is located on a same package. The command may be a write command. The control circuitry may cause the memory device to provide a Hi_z ODT setting during a write operation to the separate memory device.

### Example 4

The memory device of example 1, the memory device may be located on a first package that includes at least one other memory device. The memory device may be arranged to be a terminating memory device for the first package. The separate memory device may be located on a second package. The first group identifier may be assigned to the second package, the first group identifier to indicate that the separate memory device is located on a different package.

### Example 5

The memory device of example 4, the command may be a read command. The control circuitry may cause the memory device to provide a first ODT setting during a read operation if the second package is located adjacent to or near to the first package or provide a second ODT setting during the read operation if the second package is not located adjacent to the first package.

### Example 6

The memory device of example 1, the command may be received from a controller of a storage device.

### Example 7

The memory device of example 6, the memory device may include non-volatile types of memory, the storage device is a solid state drive.

### Example 8

The memory device of example 7, the non-volatile types of memory may include a phase change memory, a nanowire memory, FeTRAM, an anti-ferroelectric memory, a resistive memory including a metal oxide base, CB-RAM, a spintronic magnetic junction memory, a MTJ memory, a domain wall (DW) and spin orbit transfer (SOT) memory, a thyristor based memory array, MRAM that incorporates memristor technology or STT-MRAM.

### Example 9

An example apparatus may include I/O interface circuitry to couple with a first memory device. The apparatus may also include circuitry to execute program logic, the program logic may program a first register at the first memory device via the I/O interface circuitry to cause the first register to indicate multiple ODT types to select when the first memory device is a terminating memory device for a first group of memory devices. The multiple ODT types may be based on whether a read command or a write command is to be executed by a second memory device included in the first group of memory device or is to be executed by a third memory device included in a second group of memory devices. The program logic may also program a second register at the first memory device via the I/O interface circuitry to cause the second register to indicate at least two ODT types having separate ODT settings to apply based on whether a write command is to be executed by the second memory device or the third memory device.

### Example 10

The apparatus of example 9, the first group of memory devices may be located on a first package assigned a first group identifier, the second group of memory devices located on a second package assigned to a second group identifier. For this example, a fourth memory device included in a third group of memory devices is located on a third package assigned a third group identifier. The first and the second and the third packages may be coupled to the I/O interface circuitry via a same data bus, the second package located adjacent or near to the first package, the third package not located adjacent to the first package.

### Example 11

The apparatus of example 10, the program logic may also program a third register at the first memory device to indicate a first ODT setting and a second ODT setting to selectively apply when the first memory device is the terminating memory device for the first group of memory devices and the command is a read command. For this example, the first memory device may apply the first ODT setting if the read command is to the third memory device or is to apply the second ODT setting if the read command is to the fourth memory device.

### Example 12

The apparatus of example 9, the first, the second and the third memory devices may include non-volatile types of memory. The apparatus may be a controller for a solid state drive that includes the first, the second and the third memory devices.

### Example 13

The apparatus of example 12, the non-volatile types of memory may include a phase change memory, a nanowire memory, FeTRAM, an anti-ferroelectric memory, a resistive memory including a metal oxide base, CB-RAM, a spintronic magnetic junction memory, a MTJ memory, a domain wall (DW) and spin orbit transfer (SOT) memory, a thyristor based memory array, MRAM that incorporates memristor technology or STT-MRAM.

### Example 14

A storage device may include a controller having I/O interface circuitry to couple with multiple groups of memory devices via a same data channel. The storage device may also include a memory device of a first group of the multiple groups of memory devices. The memory device may include one or more registers arranged to maintain ODT settings. The memory device may also include control circuitry to receive an indication that a command from the controller is to be executed by a separate memory device coupled with the same data channel. The circuitry may also read the one or more registers to determine what ODT setting to apply during execution of the command based on a first group identifier that indicates the separate memory device's proximity to the memory device and based on whether the command is a read command or a write command.

### Example 15

The storage device of example 14, the first group of the multiple groups of memory devices may be located on a first package, the first group also includes the separate memory device, the memory device arranged to be a terminating memory device for the first group.

### Example 16

The storage device of example 15, the first group identifier may be assigned to the first group to indicate that the separate memory device is located on a same package. The command may be a write command, the control circuitry to cause the memory device to provide a Hi_z ODT setting during a write operation to the separate memory device.

### Example 17

The storage device of example 14, the first group of the multiple groups of memory devices may be located on a first package. The first group may also include the separate memory device. The memory device may be arranged to be a terminating memory device for the first group. The separate memory device may be included in a second group of the multiple groups of memory devices that are located on a second package. The first group identifier may be assigned to the second group, the first group identifier to indicate that the separate memory device is located on a different package.

### Example 18

The storage device of example 17, the command may be a read command. The control circuitry may cause the memory device to provide a first ODT setting during a read operation if the second package is located adjacent to or near to the first package or provide a second ODT setting during the read operation if the second package is not located adjacent to the first package.

### Example 19

The storage device of example 14, the memory device may include non-volatile types of memory. The storage device may be a solid state drive.

### Example 20

The storage device of example 19, the non-volatile types of memory may include a phase change memory, a nanowire memory, FeTRAM, an anti-ferroelectric memory, a resistive memory including a metal oxide base, CB-RAM, a spintronic magnetic junction memory, a MTJ memory, a domain wall (DW) and spin orbit transfer (SOT) memory, a thyristor based memory array, MRAM that incorporates memristor technology or STT-MRAM.

### Example 21

An example method may include receiving, at circuitry for a memory device, an indication that a command is to be executed by a separate memory device coupled with a same data channel. The method may also include reading one or more registers arranged to maintain ODT settings to determine what ODT setting to apply during execution of the command based on a first group identifier that indicates the separate memory device's proximity to the memory device and based on whether the command is a read command or a write command.

### Example 22

The method of example 21, the memory device may be located on a first package that includes the separate memory device. The memory device may be arranged to be a terminating memory device for the first package.

### Example 23

The method of example 22, first group identifier may be assigned to the first package indicating that the separate memory device is located on a same package. The command may be a write command, the method may also include causing the memory device to provide a Hi_z ODT setting during a write operation to the separate memory device.

### Example 24

The method of example 21, the memory device may be located on a first package that includes at least one other memory device. The memory device may be arranged to be a terminating memory device for the first package. The separate memory device may be located on a second package, the first group identifier assigned to the second package, the first group identifier to indicate that the separate memory device is located on a different package.

### Example 25

The method of example 24, the command may be a read command, the method may also include causing the memory device to provide a first ODT setting during a read operation if the second package is located adjacent to or near to the first package or provide a second ODT setting during the read operation if the second package is not located adjacent to the first package.

### Example 26

The method of example 21, the command may be received from a controller of a storage device.

### Example 27

The method of example 26, the memory device may include non-volatile types of memory, the storage device may be a solid state drive.

### Example 28

An example at least one machine readable medium may include a plurality of instructions that in response to being executed by a system may cause the system to carry out a method according to any one of examples 21 to 27.

### Example 29

An example apparatus may include means for performing the methods of any one of examples 21 to 27.

### Example 30

An example method may include programming a first register at a first memory device coupled with a controller via I/O interface circuitry to cause the first register to indicate multiple ODT types to select when the first memory device is a terminating memory device for a first group of memory devices. The multiple ODT types may be based on whether a read command or a write command is to be executed by a second memory device included in the first group of memory devices or is to be executed by a third memory device included in a second group of memory devices. The method may also include programming a second register at the first memory device via the I/O interface circuitry to cause the second register to indicate at least two ODT types having separate ODT settings to apply based on whether a write command is to be executed by the second memory device or the third memory device.

### Example 31

The method of example 30, the first group of memory devices may be located on a first package assigned a first group identifier. The second group of memory devices may be located on a second package assigned to a second group identifier. For this example, a fourth memory device included in a third group of memory devices is located on a third package assigned a third group identifier, the first and the second and the third packages coupled to the I/O interface circuitry via a same data bus. The second package may be located adjacent or near to the first package, the third package not located adjacent to the first package.

### Example 32

The method of example 31 may also include programming a third register at the first memory device to indicate a first ODT setting and a second ODT setting to selectively apply when the first memory device is the terminating memory device for the first group of memory devices and the command is a read command. For this example, the first memory device is to apply the first ODT setting if the read command is to the third memory device or is to apply the second ODT setting if the read command is to the fourth memory device.

### Example 33

The method of example 32, the first, the second and the third memory devices may include non-volatile types of memory, the controller may be a controller for a solid state drive that includes the first, the second and the third memory devices.

### Example 33

An example at least one machine readable medium may include a plurality of instructions that in response to being executed by a system may cause the system to carry out a method according to any one of examples 31 to 33.

### Example 34

An example apparatus may include means for performing the methods of any one of examples 31 to 33.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A memory device comprising:
one or more registers arranged to maintain on-die termination (ODT) settings; and
control circuitry to:
receive an indication that a command is to be executed by a separate memory device coupled with a same data channel;
read the one or more registers to determine what ODT setting to apply during execution of the command based on a first group identifier that indicates the separate memory device's proximity to the memory device and based on whether the command is a read command or a write command.

2. The memory device of claim 1, comprising the memory device located on a first package that includes the separate memory device, the memory device arranged to be a terminating memory device for the first package.

3. The memory device of claim 2, comprising the first group identifier assigned to the first package to indicate that the separate memory device is located on a same package, the command is a write command, the control circuitry to cause the memory device to provide a Hi_z ODT setting during a write operation to the separate memory device.

4. The memory device of claim 1, comprising the memory device located on a first package that includes at least one other memory device, the memory device arranged to be a terminating memory device for the first package, the separate memory device located on a second package, the first group identifier assigned to the second package, the first group identifier to indicate that the separate memory device is located on a different package.

5. The memory device of claim 4, comprising the command is a read command, the control circuitry to cause the memory device to provide a first ODT setting during a read operation if the second package is located adjacent to or near to the first package or provide a second ODT setting during the read operation if the second package is not located adjacent to the first package.

6. The memory device of claim 1, comprising the command is received from a controller of a storage device.

7. The memory device of claim 6, comprising the memory device including non-volatile types of memory, the storage device is a solid state drive.

8. The memory device of claim 7, the non-volatile types of memory comprising a phase change memory, a nanowire memory, a ferroelectric transistor random access memory (FeTRAM), an anti-ferroelectric memory, a resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory array, a magnetoresistive random access memory (MRAM) that incorporates memristor technology or a spin transfer torque MRAM (STT-MRAM).

9. An apparatus comprising:
input/output (I/O) interface circuitry to couple with a first memory device; and
circuitry to execute program logic, the program logic to:
program a first register at the first memory device via the I/O interface circuitry to cause the first register to indicate multiple on-die termination (ODT) types to select when the first memory device is a terminating memory device for a first group of memory devices, the multiple ODT types based on whether a read command or a write command is to be executed by a second memory device included in the first group of memory device or is to be executed by a third memory device included in a second group of memory devices; and
program a second register at the first memory device via the I/O interface circuitry to cause the second register to indicate at least two ODT types having separate ODT settings to apply based on whether a write command is to be executed by the second memory device or the third memory device.

10. The apparatus of claim 9, comprising the first group of memory devices located on a first package assigned a first group identifier, the second group of memory devices located on a second package assigned to a second group identifier, wherein a fourth memory device included in a third group of memory devices is located on a third package assigned a third group identifier, the first and the second and the third packages coupled to the I/O interface circuitry via a same data bus, the second package located adjacent or near to the first package, the third package not located adjacent to the first package.

11. The apparatus of claim 10, further comprising the program logic to:
program a third register at the first memory device to indicate a first ODT setting and a second ODT setting to selectively apply when the first memory device is the terminating memory device for the first group of memory devices and the command is a read command, wherein the first memory device is to apply the first ODT setting if the read command is to the third memory device or is to apply the second ODT setting if the read command is to the fourth memory device.

12. The apparatus of claim 9, comprises the first, the second and the third memory devices including non-volatile types of memory, the apparatus is a controller for a solid state drive that includes the first, the second and the third memory devices.

13. The apparatus of claim 12, the non-volatile types of memory comprising a phase change memory, a nanowire memory, a ferroelectric transistor random access memory (FeTRAM), an anti-ferroelectric memory, a resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory array, a magnetoresistive random access memory (MRAM) that incorporates memristor technology or a spin transfer torque MRAM (STT-MRAM).

14. A storage device comprising:
a controller having input/output (I/O) interface circuitry to couple with multiple groups of memory devices via a same data channel; and
a memory device of a first group of the multiple groups of memory devices, the memory device to include:
one or more registers arranged to maintain on-die termination (ODT) settings; and
control circuitry to:
receive an indication that a command from the controller is to be executed by a separate memory device coupled with the same data channel;
read the one or more registers to determine what ODT setting to apply during execution of the command based on a first group identifier that indicates the separate memory device's proximity to the memory device and based on whether the command is a read command or a write command.

15. The storage device of claim 14, comprising the first group of the multiple groups of memory devices is located on a first package, the first group also includes the separate memory device, the memory device arranged to be a terminating memory device for the first group.

16. The storage device of claim 15, comprising the first group identifier assigned to the first group to indicate that the separate memory device is located on a same package, the command is a write command, the control circuitry to cause the memory device to provide a Hi_z ODT setting during a write operation to the separate memory device.

17. The storage device of claim 14, comprising the first group of the multiple groups of memory devices is located on a first package, the first group also includes the separate memory device, the memory device arranged to be a terminating memory device for the first group, the separate memory device included in a second group of the multiple groups of memory devices that are located on a second package, the first group identifier assigned to the second group, the first group identifier to indicate that the separate memory device is located on a different package.

18. The storage device of claim 17, comprising the command is a read command, the control circuitry to cause the memory device to provide a first ODT setting during a read operation if the second package is located adjacent to or near to the first package or provide a second ODT setting during the read operation if the second package is not located adjacent to the first package.

19. The storage device of claim 14, comprising the memory device including non-volatile types of memory, the storage device is a solid state drive.

20. The storage device of claim 19, the non-volatile types of memory comprising a phase change memory, a nanowire memory, a ferroelectric transistor random access memory (FeTRAM), an anti-ferroelectric memory, a resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory array, a magnetoresistive random access memory (MRAM) that incorporates memristor technology or a spin transfer torque MRAM (STT-MRAM).
